(19) United States
(12) Patent Application Publication
(10) Pub. No.: US 2025/0237335 A1
(43) Pub. Date: Jul. 24, 2025

(54) Fluid connector assembly

(71) Applicant: Nvidia Corporation, Santa Clara, CA (US)

(72) Inventors: Travis Gaskill, San Jose, CA (US); Jiaheng Zhang, Santa Clara, CA (US); Pravir Das, McLean, VA (US); MJ Jeon, Pleasanton, CA (US); Seungkug Park, San Jose, CA (US)

(21) Appl. No.: 18/420,815

(22) Filed: Jan. 24, 2024

(51) Int. Cl. F16L 27/12; B67D 7/80; F16L 3/12

(52) U.S. Cl. CPC F16L 27/125; B67D 7/80; F16L 3/1215; B67D 2210/00031; B67D 2210/00049; B67D 2210/00062; B67D 2210/00104

(57) ABSTRACT

A connector assembly includes: (i) a first connector having a first housing and first pipes to flow fluid, (ii) a second connector having a second housing and second pipes to flow the fluid, and (iii) a blocker that has openings, and is disposed between the first pipes and the second pipes, and: (a) in a first position, the first pipes are facing the second pipes, respectively, but the blocker is configured to block flowing of the fluid between the first pipes and the second pipes, and (b) in a second position, in response to a rotation of at least a first portion of the connector assembly from the first position, relative to a second portion of the connector assembly, about a longitudinal axis of the connector assembly, the blocker is configured to enable the flowing by aligning the openings with the first pipes, and with the second pipes, respectively.

### FIELD OF THE INVENTION

The present invention relates generally to a fluid connector assembly, and particularly to a connector assembly for fluid-based cooling of electronic systems.

### BACKGROUND OF THE INVENTION

Various techniques for dissipating heat generated in switch systems are known in the art.

### SUMMARY OF THE INVENTION

An embodiment of the present invention that is described herein provides a connector assembly, including: (i) a first connector including a first housing and one or more first pipes to flow fluid, (ii) a second connector including a second housing and one or more second pipes to flow the fluid, and (iii) a blocker disposed between the one or more first pipes and the one or more second pipes, the blocker has one or more openings, (a) in a first position, the one or more first pipes are facing the one or more second pipes, respectively, but the blocker is to block flowing of the fluid between the one or more first pipes and the one or more second pipes, and (b) in a second position, in response to a rotation of at least a first portion of the connector assembly from the first position, relative to a second portion of the connector assembly, about a longitudinal axis of the connector assembly, the blocker is to enable the flowing by aligning the one or more openings with the one or more first pipes, and with the one or more second pipes, respectively.

In some embodiments, the first portion of the connector assembly includes one or both of the first and second housings, and the second portion of the connector assembly includes the one or more first and second pipes.

In other embodiments, the first and second housings include first and second pipe connectors and first and second shells, respectively, and the first and second pipe connectors are to connect between (i) the first and second shells, and (ii) the one or more first and second pipes, respectively, and the first and second shells are to fit over the first and second pipe connectors, respectively.

In yet other embodiments, the first and second shells are to rotate about the longitudinal axis, relative to the first and second pipe connectors, respectively, so as to switch a position of the connector assembly between the first position and the second position.

In some embodiments, (i) the first and second pipe connectors, and (ii) the one or more first and second pipes are static while the first and second shells are to rotate about the longitudinal axis. In other embodiments, the first and second shells are static while (i) the first and second pipe connectors, and (ii) the one or more first and second pipes are to rotate about the longitudinal axis. In yet other embodiments, the blocker includes a plate that is part of the first housing.

In some embodiments, the blocker further includes an additional plate that is part of the second housing. In other embodiments, the one or more first pipes and the one or more second pipes do not overlap the longitudinal axis of the connector assembly.

In some embodiments, the one or more second pipes include multiple second pipes that are merging into a single barb within the second connector. In other embodiments, the single barb overlaps the longitudinal axis of the connector assembly.

There is additionally provided, in accordance with an embodiment of the present invention, a method including in a connector assembly that includes: (i) a first connector including a first housing and one or more first pipes to flow fluid, (ii) a second connector including a second housing and one or more second pipes to flow the fluid, and (iii) a blocker disposed between the one or more first pipes and the one or more second pipes, and having one or more openings, mating the first and second housings in a first position in which (a) the one or more first pipes are facing the one or more second pipes, respectively, but (b) flowing of the fluid between the one or more first pipes and the one or more second pipes is blocked by the blocker. The first position is switched to a second position by rotating about a longitudinal axis of the connector assembly, at least a first portion of the connector assembly relative to a second portion of the connector assembly, thereby the one or more openings are aligned with the one or more first pipes and with the one or more second pipes, respectively, to enable the flowing of the fluid.

The present invention will be more fully understood from the following detailed description of the embodiments thereof, taken together with the drawings in which:

### BRIEF DESCRIPTION OF THE DRAWINGS

FIG. 1 is a schematic, pictorial illustration of a connector assembly of a fluid-based cooling apparatus of an electronic system, in accordance with an embodiment of the present invention;

FIG. 2 is a schematic exploded view of the connector assembly of FIG. 1, in accordance with an embodiment of the present invention;

FIG. 3 is a schematic, pictorial illustration of a pipe connector of the connector assembly of FIG. 1, in accordance with an embodiment of the present invention;

FIG. 4 is a schematic, pictorial illustration of shells of the connector assembly of FIG. 1 in an open position, in accordance with an embodiment of the present invention;

FIG. 5 is a schematic, pictorial illustration of shells of the connector assembly of FIG. 1 in a closed position, in accordance with an embodiment of the present invention;

FIG. 6 is a flow chart that schematically illustrates a method for controlling flowing of fluid through the connector assembly of FIG. 1, in accordance with an embodiment of the present invention; and

FIG. 7 is a sectional view of a connector assembly of a fluid-based cooling apparatus, in accordance with another embodiment of the present invention.

### DETAILED DESCRIPTION OF EMBODIMENTS

### Overview

Electronic systems typically comprise active and passive electronic devices that generate heat while being operated. Various techniques for dissipating the heat have been developed. Some of these techniques include fluid-based cooling, in which fluid flows through the electronic system and dissipates the heat generated by the electronic devices. Some fluid-based cooling systems include flow disconnects, such as the Danfoss Hansen® FD83 family of quick-disconnect couplings supplied by Danfoss (Nordborg, 81 Nordborgvej, Denmark), and the TDU 24 family of products supplied by Staubli (Pfäffikon, Switzerland).

Embodiments of the present invention that are described hereinbelow provide a fluid-based quick-disconnect (QD), also referred to herein as a connector assembly, which is configured to seal and unseal a flow path of the fluid using a rotational movement of the housing of the connector assembly. It is noted that the connector assembly has no components in the flow path of the fluid, and thereby allows for reduced pressure drop of the fluid.

In some embodiments, the connector assembly comprises (i) a first connector having a first housing and one or more (e.g., two) first pipes configured to flow fluid, and (ii) a second connector having a second housing and one or more (e.g., two) second pipes configured to flow the fluid.

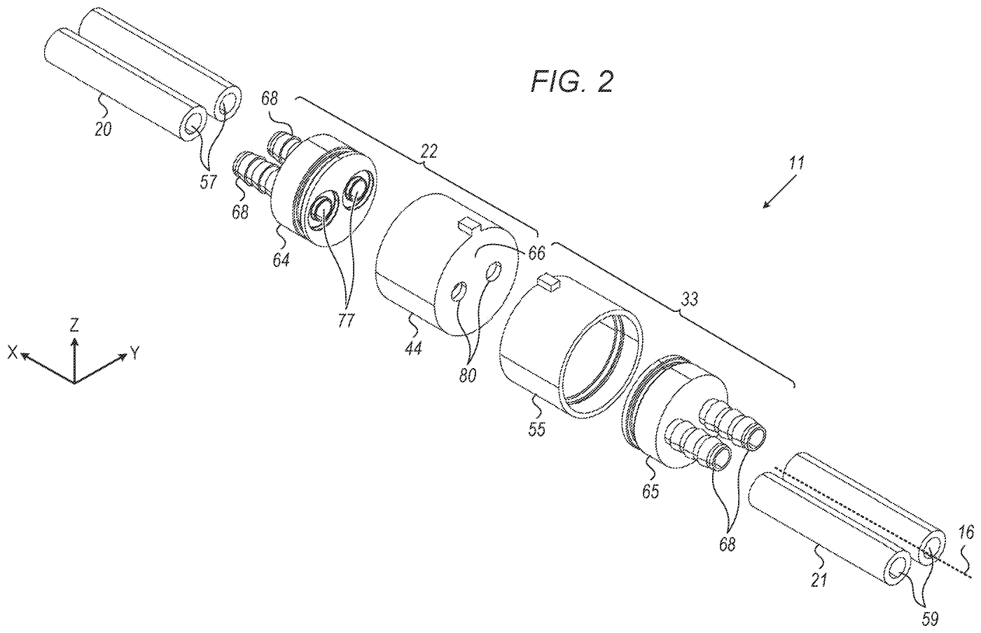

In some embodiments, the connector assembly comprises a blocker, which is disposed between the first and second pipes (e.g., between the first and second housings). In an example implementation, the blocker comprises a plate having one or more openings. In the present example, the blocker has two openings, and the diameter of the openings is approximately similar to the diameters of the first and second pipes, as described in detail in FIGS. 2-5 below.

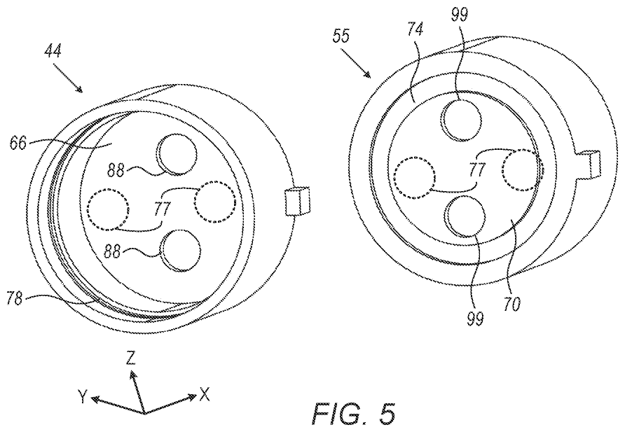

In some embodiments, in a first position the first and second pipes are facing one another (e.g., the openings of the one or more first pipes and the openings of the one or more second pipes are aligned along a longitudinal axis of the connector assembly), and the openings of the blocker are not aligned with the openings of the pipes along the longitudinal axis. In such embodiments, in the first position the plate of the blocker is configured to block the flowing of the fluid between the first and second pipes. The first position is depicted in more detail in FIG. 5 below.

In some embodiments, in a second position the first and second pipes are facing one another, and the openings of the blocker are aligned with the openings of the pipes along the longitudinal axis of the connector assembly. In such embodiments, in the second position the connector assembly is configured to enable the flowing of the fluid through the connector assembly, i.e., between the first and second pipes. The second position is depicted in more detail in FIG. 4 below.

In some embodiments, the first and second housings comprise first and second pipe connectors and first and second shells, respectively. The first and second pipe connectors are configured to fit in the first and second shells, and to connect between the first and second pipes and the first and second shells, respectively. This configuration is presented and described in detail in FIG. 2 below.

In some embodiments, at least one of, and typically both the first and second shells comprise the blocker. For example, the blocker(s) implemented as one or more plates in the first and/or second shells, as described in detail in FIGS. 2, 4 and 5 below.

In some embodiments, the connector assembly is fully assembled after fitting the first and second shells over the first and second pipe connectors, respectively, and mating the first and second shells.

In some embodiments, after the connector assembly has been assembled, the first and second shells are configured to rotate about the longitudinal axis for switching between first and second positions. It is noted that the pipes and pipe connectors are approximately static, in order to reduce the twisting of at least one of the pipes about the longitudinal axis.

In some embodiments, the connector assembly comprises first and second brackets, which are fitted over the first and second pipes, respectively, and are configured to prevent the twisting described above.

In one implementation, the connector assembly is switched to the first position in response to rotating the first and second shells, e.g., clockwise, about the longitudinal axis. Similarly, in response to rotating the first and second shells counterclockwise the connector assembly is switched to the second position. In another implementation, the switching between the first and second positions may be carried out using any other technique and/or sequence, as described in the detailed description below.

### System Description

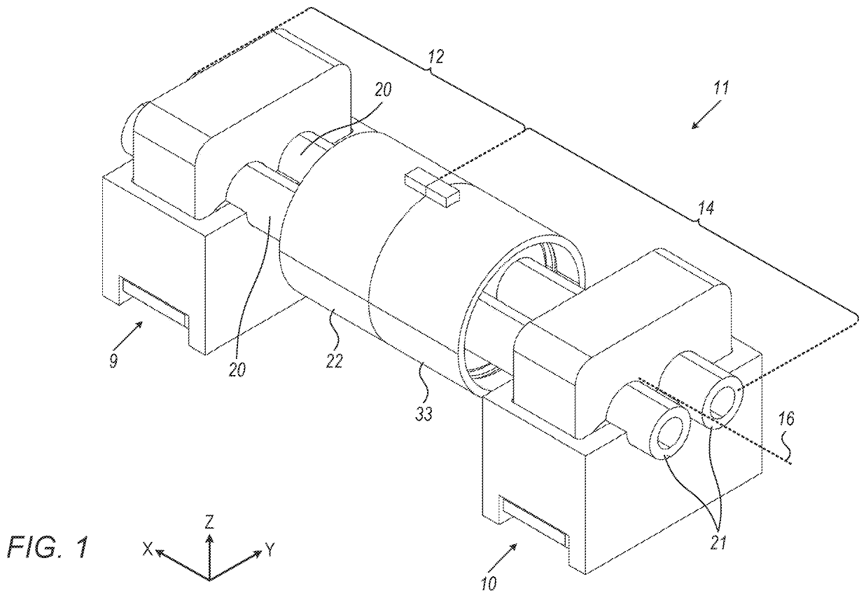

FIG. 1 is a schematic, pictorial illustration of a connector assembly 11 of a fluid-based cooling apparatus of an electronic system, in accordance with an embodiment of the present invention.

In some embodiments, connector assembly 11 comprises connectors 12 and 14 coupled to one another and having housings 22 and 33 (described in detail in FIGS. 2-6 below), and pipes 20 and 21, respectively. In some embodiments, connectors 12 and 14 comprise at least a portion of pipes 20 and 21, respectively. In the present example, connector assembly 11 comprises brackets 9 and 10, which are configured to fixate pipes 20 and 21, respectively, as will be described in more detail below. It is noted that in the present configuration, pipes 20 and 21 are similar to one another (e.g., made from the same material and having the same inner and outer diameter), and receive different numeral solely for the sake of presentation of embodiments of the present disclosure. In other configurations, pipes 20 and 21 may differ from one another in at least one feature.

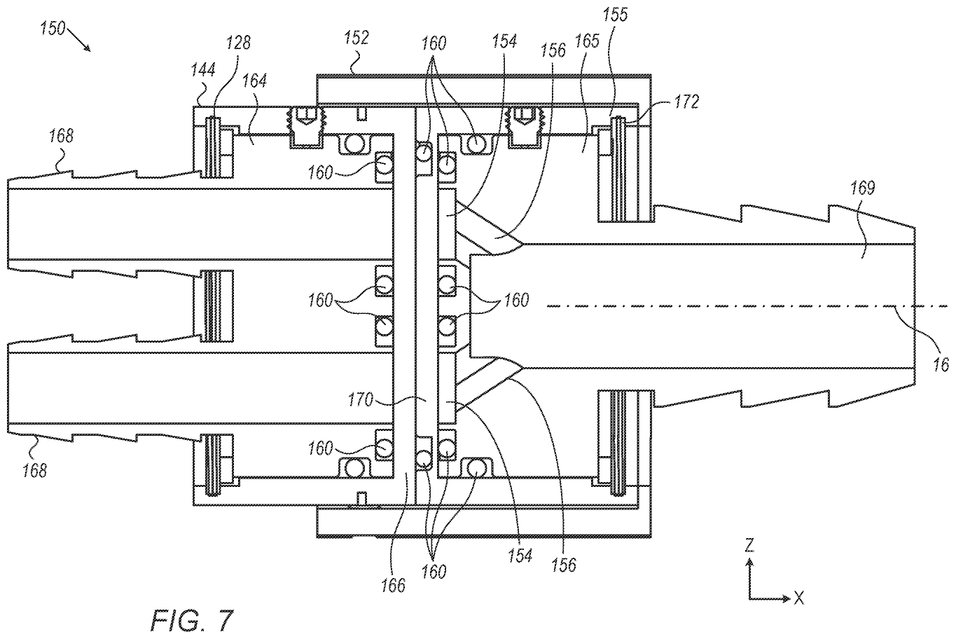

In some embodiments, each of pipes 20 and 21 comprises two similar pipes, none of the pipes overlaps a longitudinal axis 16 of connector assembly 11, but in alternative embodiments (e.g., shown in FIG. 7 below) at least one of the pipes overlaps longitudinal axis 16. In the present example, longitudinal axis 16 is approximately parallel to an X-axis of an XYZ coordinate system, which is also the longitudinal axis of connector assembly 11.

In other embodiments, at least one of connectors 12 and 14 may have any other suitable number of (one or more) pipes 20 and 21, respectively.

In some embodiments, housings 22 and 33 are mated (e.g., coupled) while assembling connectors 12 and 14, but after being assembled, connector assembly 11 remains in a closed position and blocks the flowing of the fluid between pipes 20 and 21.

In some embodiments, after the mating, at least a first portion of connector assembly 11 is being rotated from the closed position, relative to a second portion of connector assembly 11. In the present example, at least part of housings 22 and 33 is being rotated, e.g., relative to pipes 20 and 21, in order to arrange the components of connector assembly 11 in an open position. It is noted that in the open position, connector assembly 11 is configured to enable the flowing of the fluid between pipes 20 and 21, as will be described in detail in FIGS. 2-4 below.

In alternative embodiments, after being mated, housings 22 and 33 may be rotated separately, e.g., at different time intervals, in order to switch the position of connector assembly 11 from the closed position to the open position, as will be described in detail, for example, in FIG. 5 below.

Additionally, or alternatively, housings 22 and 33 may be rotated differently in order to switch the position of connector assembly 11 from the closed position to the open position. For example, in order to switch from the closed position to the open position, housing 22 may be rotated clockwise and housing 33 may be rotated counterclockwise, as will be described in detail in FIG. 4 below.

FIG. 2 is a schematic exploded view of connector assembly 11, in accordance with an embodiment of the present invention.

In some embodiments, housing 22 comprises a shell 44 and a pipe connector 64 configured to fit in shell 44. Similarly, housing 33 comprises a shell 55 and a pipe connector 65 configured to fit in shell 55. In the present configuration, the structure of pipe connectors 64 and 65 is similar to one another, but in other embodiments, the structure of pipe connectors 64 and 65 may differ from one another, as will be described in detail, for example, in FIGS. 4 and 5 below.

In some embodiments, pipes 20 have openings 57, pipes 21 have openings 59, and both pipe connectors 64 and 65 have adapters 68, and openings 77. In the example of FIG. 2, adapters 68 are configured to fit in pipes 20 and 21, and to couple between (i) pipes 20 and 21, and (ii) pipe connectors 64 and 65, respectively.

In some embodiments, shell 44 has a blocker 66, which is disposed between the pairs of pipes 20 and pipes 21. In the present example, shell 44 comprises blocker 66, which is formed (as a single piece) as part of shell 44. In other words, blocker 66 comprises a plate that is part of shell 44 of housing 22.

In some embodiments, shell 55 also has a blocker, which is shown for example in FIGS. 4 and 5 below. The blocker of shell 55 may have a similar structure to that of blocker 66 described herein.

In some embodiments, blocker 66 has two openings 88 having a suitable diameter to mate with openings 77 of pipe connectors 64 and 65 (e.g., openings 77 and 88 may have approximately similar diameter). The number of openings 77 and 88 is typically (but not necessarily) similar to the number of the pipes (two in the present example).

In other embodiments, instead of blocker 66, the blocker of connector assembly 11 may comprise a plate (e.g., shaped as a disk), which is not part of shells 44 and 55, and may be disposed between shells 44 and 55. In such embodiments, shell 44 may be open along the X-axis, and the disk-shaped blocker has openings 77, e.g., similar to that of blocker 66 described above.

In alternative embodiments, only one of shells 44 and 55 may comprise a blocker. The functionality of blocker 66 is described in detail below.

In some embodiments, connector assembly 11 may be arranged in at least an open position and a closed position. In the example of FIG. 2, the components of connector assembly 11 are arranged in an open position, such that openings 57 and 59 are aligned with one another along longitudinal axis 16, and cooling fluid could flow between pipes 20 and 21 and through connectors 12 and 14. In the present configuration, when connectors 12 and 14 are mated, connector assembly 11 is arranged in a closed position, and only after rotating shells 44 and 55 relative to pipes 20 and 21, connector assembly 11 is switched to the open position.

In some embodiments, pipe connectors 64 and 65 and pipes 20 and 21 are typically static, and shells 44 and 55 are configured to rotate, relative to pipe connectors 64 and 65 and to pipes 20 and 21, in order to operate connector assembly 11 in the open position. In the present configuration, pipe connectors 64 and 65 are static in order to prevent (or at least reduce) the twisting of at least one of pipes 20 and 21 about longitudinal axis 16. Moreover, brackets 9 and 10 (shown in FIG. 1 above) that are fitted over pipes 20 and 21, respectively, are configured to fixate the pipes, and thereby, to prevent any twisting or undesired movement of pipes 20 and 21.

In such embodiments, connector assembly 11 is configured to enable: (i) quick mating of housings 22 and 33 of connectors 12 and 14, respectively, (ii) quick switching between the open position and the closed position (by rotating shells 44 and 55, e.g., clockwise and counterclockwise about longitudinal axis 16, relative to pipe connectors 64 and 65), and (iii) quick disconnect (QD) (i.e., separation) between housings 22 and 33 of connectors 12 and 14, respectively.

In alternative embodiments, shells 44 and 55 are typically static, and pipe connectors 64 and 65 and pipes 20 and 21 are configured to rotate about longitudinal axis 16 relative to shells 44 and 55, in order to operate connector assembly 11 in the open and closed positions.

The arrangement of connector assembly 11 in the open position and in the closed position are described in detail in FIGS. 4 and 5 below, respectively.

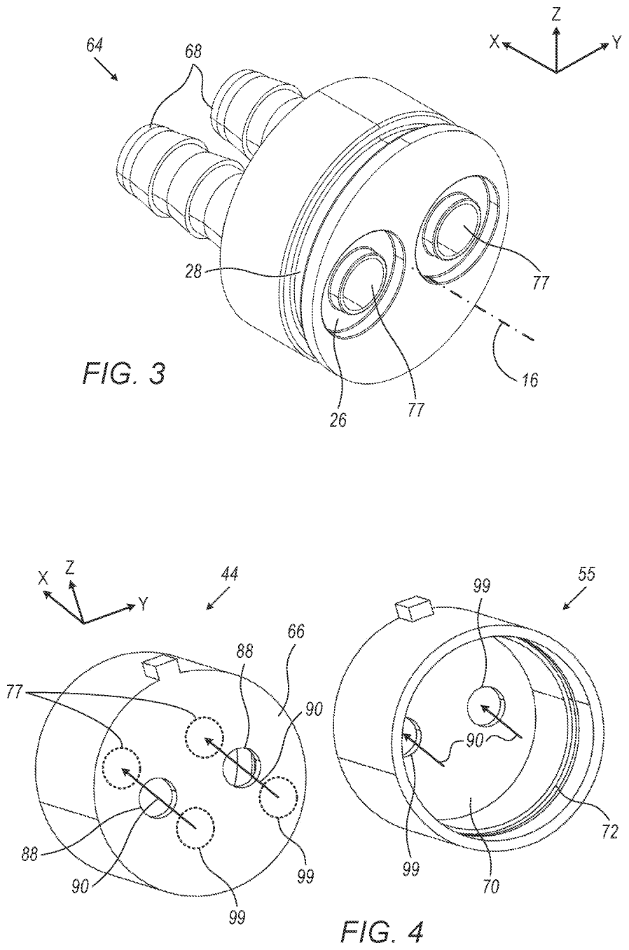

FIG. 3 is a schematic, pictorial illustration of pipe connector 64 of connector assembly 11, in accordance with an embodiment of the present invention.

In some embodiments, pipe connector 64 has openings 77 configured to flow the cooling fluid, and sealing rings (e.g., O-rings, not shown) configured to retain the fluid sealed within connector assembly 11. In the present example, the sealing rings are fitted in trenches 26 surrounding openings 77.

In some embodiments, pipe connector 64 has a recess 28, which is an O-ring groove configured to fit an O-ring to prevent leaking while rotating shell 44 relative to pipe connector 64. As described above, when mating housings 22 and 33 of connectors 12 and 14, connector assembly 11 is typically in a closed position and the fluid is not flowing between pipes 20 and 21, and the open position is obtained after rotating shells 44 and 55 relative to pipe connectors 64 and 65, respectively.

Moreover, as described in FIG. 2 above, (i) adapters 68 of pipe connector 64 are configured to fit in pipes 20 for flowing the fluid, and (ii) the structure of pipe connectors 64 and 65 is typically (but not necessarily) similar to one another.

In some embodiments, openings 77 do not overlap longitudinal axis 16 of connector assembly 11, as also described for pipes 20 and 21 in FIG. 1 above.

FIG. 4 is a schematic, pictorial illustration of shells 44 and 55 arranged in the open position, in accordance with an embodiment of the present invention. In the present example, the open position is obtained by rotating shells 44 and 55 relative to pipe connectors 64 and 65 and pipes 20 and 21, respectively. As will be described in detail below, in the open position, in response to the rotation of at least a first portion of connector assembly 11 (e.g., one or both shells 44 and 55) from the closed position, relative to a second portion of connector assembly 11 (e.g., pipes 16 and 20, and/or pipe connectors 64 and 65), about longitudinal axis 16 of connector assembly 11, one or both of blockers 66 and 70 are configured to enable flowing of the fluid by aligning openings 77, 88 and 99 with pipes 20 and 21, respectively.

Reference is now made to shell 55. In some embodiments, shell 55 comprises a blocker 70 that in the present example has a similar structure to that of blocker 66 of shell 44. Blocker 70 has two openings 99, and shell 55 has a recess 72, which is configured to fit a retaining ring to contain pipe connector 65 inside of shell 55. The recess 72 and retaining ring enable the rotation of shell 55 relative to pipe connector 65, so as to switch between the closed position and the open position, using the same mechanism described in FIG. 3 above for shell 44 and pipe connector 64.

Reference is now made to shell 44. In some embodiments, the positions of openings 77 (of pipe connector 64) and openings 99 (of shell 55) are illustrated in dashed circles over blocker 66. Moreover, the flow direction of the fluid is presented by arrows 90 (also shown in shell 55). In some embodiments, in the open position, openings 77, 88 and 99 are all aligned along the X-axis, is also approximately parallel to the aforementioned longitudinal axis 16 of connector assembly 11.

In some embodiments, pipe connectors 64 and 65 and pipes 20 and 21 are approximately static and serve as an arbitrary frame of reference, and shells 44 and 55 are configured to rotate relative to pipe connectors 64 and 65 in order to obtain the alignment of openings 77, 88 and 99 along the X-axis. As described above, shells 44 and 55 are configured to rotate relative to pipe connectors 64 and 65 together and using the same pattern of rotation, or alternatively, at different time intervals and/or using a different pattern of rotation. In one implementation of the different rotation pattern, shell 44 is configured to be rotated clockwise and shell 55 is configured to be rotated counterclockwise. In an alternative implementation, shells 44 and 55 may be rotated in the same direction (e.g., clockwise) using different rotation angles.

In such embodiments, in response to shells 44 and 55 being rotated (e.g., relative to pipes 20 and 21) about longitudinal axis 16 of connector assembly 11, blockers 66 and 77 are configured to enable the flowing of the fluid by aligning openings 77, 88 and 99 with pipes 20 and 21.

FIG. 5 is a schematic, pictorial illustration of shells 44 and 55 in a closed position, in accordance with an embodiment of the present invention. It is noted that the closed position may be obtained, for example, in response to mating shells 44 and 55, as described for example in FIG. 2 above.

Reference is now made to shell 55. In some embodiments, shell 55 has a sealing ring 74 (e.g., an O-ring) fitted within a circular trench (not shown) surrounding blocker 70. Sealing ring 74 is configured to prevent leaks of the fluid between shells 44 and 55, and thereby, to enable the flowing of the fluid through the openings described in FIGS. 2-4 above, and through pipes 20 and 21 of connector assembly 11. In the present configuration of connector assembly 11, the openings of connector assembly 11 comprise openings 77, 88, 99, and the corresponding openings (not shown) of pipe connectors 64 and 65.

Reference is now made to shell 44. In some embodiments, the positions of openings 77 of pipe connector 64 (and the corresponding openings of pipe connector 65), are illustrated by dashed circles 77 positioned over blocker 66.

In such embodiments, pipe connector 64 and pipes 20 are facing pipe connector 65 and pipes 21, respectively, but one or both of blockers 66 and 70 are configured to block the flowing of the fluid through connector assembly 11, i.e., between pipes 20 and 21.

In the embodiments described in FIGS. 2-4 above, pipe connectors 64 and 65 are typically static, and shells 44 and 55 are being rotated (e.g., relative to pipes 20 and 21) about longitudinal axis 16 (together and at the same time interval, or in separate time intervals), relative to pipe connectors 64 and 65. In response to the rotation, the position of connector assembly 11 may be switched between the closed position and the open position, as described in detail in FIGS. 2-4 above.

In some embodiments, shell 44 has a recess 78, which is configured to fit a retaining ring to contain pipe connector 64 (shown in FIG. 3 above) inside of shell 44. The shapes of recesses 28 and 78 are adapted to prevent leaking while rotating shell 44 relative to pipe connector 64 along the X-axis.

In other embodiments, instead of the recesses and retaining rings described in FIGS. 3-5 above, connector assembly 11 may have any other suitable mechanism prevent leaking of the fluid and to enable the rotation of shells 44 and 55 relative to pipe connectors 64 and 65.

This particular configuration of connector assembly 11 is shown by way of example, in order to illustrate certain problems that are addressed by embodiments of the present invention and to demonstrate the application of these embodiments in enhancing the performance of a cooling apparatus in an electronic system. Embodiments of the present invention, however, are by no means limited to this specific sort of example connector assembly and cooling apparatus, and the principles described herein may similarly be applied to other suitable sorts of cooling apparatus and subsystems.

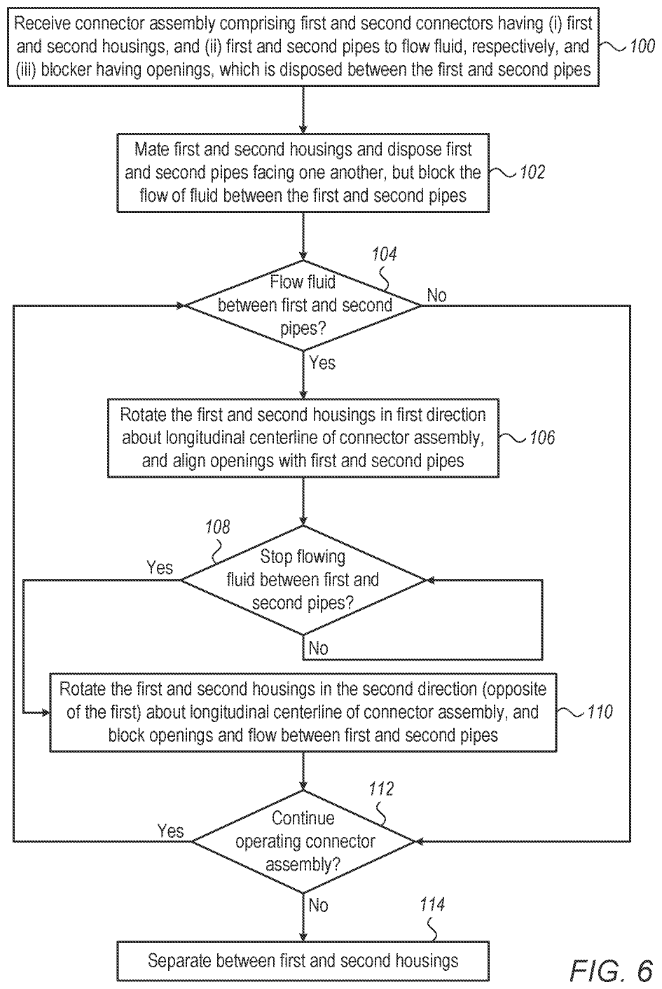

FIG. 6 is a flow chart that schematically illustrates a method for controlling the flowing of fluid through connector assembly 11, in accordance with an embodiment of the present invention.

The method begins at a connector assembly receiving step 100, with receiving connector assembly 11 that comprises connectors 12 and 14 having (i) housings 22 and 33, and (ii) pipes 20 and 21; flow the fluid, respectively, and (iii) blockers 66 and 70 having openings 88 and 99, respectively. Blockers 66 and 70 are disposed between pipes 20 and 21. The structure of connector assembly is described in detail in FIGS. 1-5 above.

At a mating step 102, housings 22 and 33 are mated and pipes 20 and 21 are disposed to face one another so that openings 57 of pipes 20 are aligned with openings 59 of pipes 21 along longitudinal axis 16, but the flow of the fluid between pipes 20 and 21 is blocked. The operation of step 102 is described in detail in FIGS. 2 and 5 above.

At a first decision step 104, an operator of (or a controller configured to control) connector assembly 11 decides whether or not to flow the fluid between pipes 20 and 21.

In case the decision in step 104 is to flow the fluid, the method proceeds to a step 106. At step 106, housings 22 and 33 are being rotated, relative to pipes 20 and 21, about longitudinal axis 16. In response to the rotation, openings 77, 88 and 99 are aligned along longitudinal axis 16 (i) with one another, and (ii) with openings 57 and 59 of pipes 20 and 21, respectively. In the present example, the rotation of both shells 44 and 55 is in the same direction, e.g., counterclockwise.

In case the decision in step 104 is not to flow the fluid, the method proceeds to a second decision step 112. At step 112, the operator, or the controller of connector assembly 11 decides whether or not to continue the operation of connector assembly 11.

In case the decision in step 112 is to continue the operation of connector assembly 11, the method loops back to step 104. Alternatively, the method proceeds to a separation step 114 for disconnecting between housings 22 and 33, and thereby, disassembling at least part of connector assembly 11.

After concluding step 106 above, the method proceeds to a third decision step 108. At step 108, the operator, and/or the controller of connector assembly 11 decides whether or not to stop flowing the fluid between pipes 20 and 21.

In case the decision in step 108 is to stop flowing the fluid between pipes 20 and 21, the method proceeds to a flow blocking step 110. At step 110, shells 44 and 55 of housings 22 and 33, respectively, are being rotated relative to pipes 20 and 21 about longitudinal axis 16 in order to block the flow of the fluid between pipes 20 and 21, as described for example in FIG. 5 above. In the present example, the rotation of both shells 44 and 55 is in the same direction, clockwise, which is opposite to the counterclockwise rotation in step 106 above.

In case the decision in step 108 is to continue flowing the fluid between pipes 20 and 21, the method is retained in step 108, e.g., loops back to the decision of step 108, until the decision is to stop flowing the fluid between pipes 20 and 21, and then the method proceeds to flow blocking step 110, as described above.

In some embodiments, after concluding step 110, the method proceeds to step 112, which is described above.

The flow chart of FIG. 6 is simplified and provided by way of example, and therefore, the operation of connector assembly may comprise additional steps, instead of or in addition to the steps described above.

FIG. 7 is a sectional view of a connector assembly 150, in accordance with another embodiment of the present invention. Connector assembly 150 may replace, for example, connector assembly 11 shown in FIG. 2 above.

In some embodiments, connector assembly 150 comprises (i) a pipe connector 164 and two adapters 168 having respective structures and functionalities similar to that of pipe connector 64 and adapters 68 described in FIG. 3 above, (ii) a shell 144 having a structure and functionality similar to that of shell 44 described in FIGS. 4 and 5 above, and (iii) a blocker 166 having a structure and functionality similar to that of blocker 66 described in FIGS. 4 and 5 above.

In some embodiments, connector assembly 150 comprises a pipe connector 165 having two opening 154 aligned with the two respective adapters 168 along the X-axis. In the present configuration, openings 154 are configured to merge, via two respective pipes 156 within pipe connector 165, into a single barb 169. In the present example, barb 169 is located along and/or overlaps longitudinal axis 16. Moreover, barb 169 is fitted in a single pipe (not shown), which is extending along axis 16, so that barb 169 and the single pipe are configured to flow the fluid as will be described below. It is noted that, at the connection with openings 154, pipes 156 are facing adapters 168. In this configuration of FIG. 7, the combination of (i) pipe connector 165, (ii) openings 154, (iii) pipes 156, (iv) barb 169, and (v) the aforementioned single pipe, may replace the combination of (i) pipe connector 65, and adapters 68 of housing 33, and (ii) pipes 21, all shown in FIG. 2 above.

In some embodiments, shells 166 and 170 have recesses 128 and 172 respectively, similar to recesses 72 and 78, which are configured to fit a retaining ring to contain pipe connectors 164 and 165 inside shells 166 and 170, respectively.

In some embodiments, connector assembly 150 comprises a rotatable handle 152, which is configured to rotate one or both of shells 144 and 155 about longitudinal axis 16 in order to switch the position of connector assembly 150 between open and closed positions. It is noted that both blockers 166 and 170 have openings (not shown), typically similar to openings 88 and 99 of blockers 66 and 70, respectively, shown in FIGS. 4 and 5 above. In the open position, the fluid flows through connector assembly 150, as shown in the example of FIG. 4 above for the corresponding connector assembly 11. It is noted that in the open position of connector assembly 150, barb 169 is configured to flow the fluid, via openings 154 and pipes 156, to and/or from adapters 168.

In the example of FIG. 7, connector assembly 150 is in a closed position, and therefore, the openings of blockers 166 and 170 are not shown in the sectional view of FIG. 7. In the closed position, at least one of and typically both blockers 166 and 170 are configured to block the flowing of the fluid between adapters 168 and openings 154, as shown in the example of FIG. 5 above for the corresponding connector assembly 11.

In some embodiments, connector assembly 150 comprises multiple O-rings 160, which are fitted in respective grooves of components of connector assembly 150. O-rings 160 are configured to prevent leaking (i) while one or both of shells 144 and 155 is rotated relative to pipe connectors 164 and 165, respectively, and (ii) while connector assembly 150 is in the open position.

In some embodiments, the method of claim 6 may be implemented, mutatis mutandis, using connector assembly 150 instead of or in addition to connector assembly 11. In this implementation, in step 106 at least one of, and typically both shells 144 and 155 may be rotated counterclockwise about longitudinal axis 16 to an open position of connector assembly 150. In the open position, the openings of blockers 166 and 170 are aligned with openings 154 and with adapters 168, and the fluid is flowing between adapters 168 and barb 169, as shown for connector assembly 11 in the example of FIG. 4 above.

In the closed position shown in FIG. 7, the openings of blockers 166 and 170 are not aligned with openings 154 and with adapters 168, and therefore, the fluid is blocked and cannot flow between adapters 168 and barb 169, as shown for connector assembly 11 in the example of FIG. 5 above.

The principles described in FIGS. 1-7 above may similarly be applied to other suitable sorts of techniques for fluid-based cooling of electronic systems, and any other suitable systems, other than electronic systems, that require fluid-based cooling.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A connector assembly, comprising:
a first connector comprising a first housing and one or more first pipes to flow fluid;
a second connector comprising a second housing and one or more second pipes to flow the fluid; and
a blocker disposed between the one or more first pipes and the one or more second pipes, wherein the blocker has one or more openings, and wherein:
in a first position, the one or more first pipes are facing the one or more second pipes, respectively, but the blocker is to block flowing of the fluid between the one or more first pipes and the one or more second pipes, and
in a second position, in response to a rotation of at least a first portion of the connector assembly from the first position, relative to a second portion of the connector assembly, about a longitudinal axis of the connector assembly, the blocker is to enable the flowing by aligning the one or more openings with the one or more first pipes, and with the one or more second pipes, respectively.

2. The connector assembly according to claim 1, wherein the first portion of the connector assembly comprises one or both of the first and second housings, and the second portion of the connector assembly comprises the one or more first and second pipes.

3. The connector assembly according to claim 2, wherein the first and second housings comprise first and second pipe connectors and first and second shells, respectively, wherein the first and second pipe connectors are to connect between (i) the first and second shells, and (ii) the one or more first and second pipes, respectively, and wherein the first and second shells are to fit over the first and second pipe connectors, respectively.

4. The connector assembly according to claim 3, wherein the first and second shells are to rotate about the longitudinal axis, relative to the first and second pipe connectors, respectively, so as to switch a position of the connector assembly between the first position and the second position.

5. The connector assembly according to claim 3, wherein (i) the first and second pipe connectors, and (ii) the one or more first and second pipes are static while the first and second shells are to rotate about the longitudinal axis.

6. The connector assembly according to claim 3, wherein the first and second shells are static while (i) the first and second pipe connectors, and (ii) the one or more first and second pipes are to rotate about the longitudinal axis.

7. The connector assembly according to claim 1, wherein the blocker comprises a plate that is part of the first housing.

8. The connector assembly according to claim 7, wherein the blocker further comprises an additional plate that is part of the second housing.

9. The connector assembly according to claim 1, wherein the one or more first pipes and the one or more second pipes do not overlap the longitudinal axis of the connector assembly.

10. The connector assembly according to claim 1, wherein the one or more second pipes comprise multiple second pipes that are merging into a single barb within the second connector.

11. The connector assembly according to claim 10, wherein the single barb overlaps the longitudinal axis of the connector assembly.

12. A method, comprising:
in a connector assembly comprising: (i) a first connector comprising a first housing and one or more first pipes to flow fluid, (ii) a second connector comprising a second housing and one or more second pipes to flow the fluid, and (iii) a blocker disposed between the one or more first pipes and the one or more second pipes, and having one or more openings,
mating the t first and second housings in a first position in which (i) the one or more first pipes are facing the one or more second pipes, respectively, but (ii) flowing of the fluid between the one or more first pipes and the one or more second pipes is blocked by the blocker; and
switching from the first position to a second position by rotating about a longitudinal axis of the connector assembly, at least a first portion of the connector assembly relative to a second portion of the connector assembly, thereby aligning the one or more openings with the one or more first pipes and with the one or more second pipes, respectively, to enable the flowing of the fluid.

13. The method according to claim 11, wherein rotating the first portion of the connector assembly comprises rotating one or both of the first and second housings, and wherein the second portion of the connector assembly comprises the one or more first and second pipes.

14. The method according to claim 13, wherein the blocker comprises a plate that is part of the first housing, and wherein rotating the first and second housings about the longitudinal axis comprises rotating the plate together with the first housing.

15. The method according to claim 14, wherein the blocker further comprises an additional plate that is part of the second housing, and wherein rotating the first and second housings about the longitudinal axis comprises rotating the additional plate together with the second housing.

16. The method according to claim 13, wherein switching from the first position to the second position comprises rotating the first and second housings in a first direction, and comprising switching from the second position to the first position by rotating the first and second housings in a second direction, opposite the first direction.

17. The method according to claim 13, wherein the first and second housings comprise first and second pipe connectors and first and second shells, respectively, and wherein mating the first and second housings comprises connecting between (i) the first and second shells, and (ii) the one or more first and second pipes, respectively, using the first and second pipe connectors, and fitting the first and second shells over the first and second pipe connectors, respectively.

18. The method according to claim 17, wherein rotating the first and second housings comprises rotating the first and second shells about the longitudinal axis, relative to the first and second pipe connectors, respectively.

19. The method according to claim 17, wherein rotating the first and second housings comprises retaining the first and second pipe connectors and the one or more first and second pipes in a static position, and rotating the first and second shells about the longitudinal axis.
